(19) United States
(12) Patent Application Publication
(10) Pub. No.: US 2025/0336827 A1
(43) Pub. Date: Oct. 30, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Hyunho Chu, Suwon-si (KR); Jiwon Shin, Suwon-si (KR); Kundae Yeom, Suwon-si (KR); Sanghyeon Lee, Suwon-si (KR)

(21) Appl. No.: 18/940,153

(22) Filed: Nov. 7, 2024

(30) Foreign Application Priority Data
Apr. 26, 2024 (KR) 10-2024-0055922

(51) Int. Cl. H01L 23/532; H01L 23/00; H01L 23/31; H01L 25/18; H05K 1/18; H10B 80/00

(52) U.S. Cl. CPC H01L 23/5329; H01L 24/05; H01L 24/08; H01L 24/29; H01L 24/32; H01L 24/48; H01L 24/73; H01L 23/3128; H01L 24/80; H01L 24/94; H01L 25/18; H01L 2224/05187; H01L 2224/08145; H01L 2224/29005; H01L 2224/32225; H01L 2224/48147; H01L 2224/48227; H01L 2224/73265; H01L 2224/80895; H01L 2224/80896; H01L 2224/94; H01L 2225/06506; H01L 2225/0651; H01L 2225/06562; H01L 2924/35; H05K 1/181; H10B 80/00

(57) ABSTRACT

Disclosed are semiconductor packages and their fabrication methods. The semiconductor package comprises a package substrate, a plurality of semiconductor dies stacked on the package substrate wherein end portions of the semiconductor dies form a stepwise shape, a plurality of wires that connect the semiconductor dies to the package substrate, and a mold layer that covers the package substrate, the semiconductor dies, and the wires. Each of the semiconductor dies includes a die substrate, a die dielectric layer on the die substrate, a bonding pad on the die dielectric layer, and a first polymer layer that covers the die dielectric layer and exposes the bonding pad. A plurality of oxygen atoms are between the semiconductor dies.

### CROSS-REFERENCE TO RELATED APPLICATION

This U.S. nonprovisional application claims priority under 35 U.S.C § 119 to Korean Patent Application No. 10-2024-0055922 filed on Apr. 26, 2024, in the Korean Intellectual Property Office, the entirety of which is hereby incorporated by reference.

### BACKGROUND

A semiconductor package is provided to implement an integrated circuit chip for use in electronic products. A semiconductor package is typically configured such that a semiconductor chip is mounted on a printed circuit board (PCB) and bonding wires or bumps are used to electrically connect the semiconductor chip to the printed circuit board. With the development of electronic industry, many studies have been conducted to improve reliability and durability of semiconductor packages.

### SUMMARY

Some aspects of the present disclosure provide semiconductor packages whose size is reduced and reliability is increased.

Some aspects of the present disclosure provide methods of fabricating a semiconductor package in which defects are prevented or reduced.

The objects of the present disclosure are not limited to those mentioned above, and other objects which have not been mentioned above will be clearly understood by those skilled in the art from the following description.

According to some implementations of the present disclosure, a semiconductor package may comprise: a package substrate; a plurality of semiconductor dies stacked on the package substrate, wherein end portions of the semiconductor dies form a stepwise shape; a plurality of wires that connect the semiconductor dies to the package substrate; and a mold layer that covers the package substrate, the semiconductor dies, and the wires. Each of the semiconductor dies may include: a die substrate; a die dielectric layer on the die substrate; a bonding pad on the die dielectric layer; and a first polymer layer that covers the die dielectric layer and exposes the bonding pad. A plurality of oxygen atoms may be between the semiconductor dies.

According to some implementations of the present disclosure, a semiconductor package may comprise: a package substrate; a plurality of semiconductor dies stacked on the package substrate, wherein end portions of the semiconductor dies form a stepwise shape; a plurality of wires that connect the semiconductor dies to the package substrate; an adhesion film between the package substrate and a lowermost one of the semiconductor dies; and a mold layer that covers the package substrate, the semiconductor dies, and the wires. Each of the semiconductor dies may include: a die substrate; a die dielectric layer on the die substrate; a bonding pad on the die dielectric layer; and a polymer layer that covers the die dielectric layer and exposes the bonding pad. The adhesion film may include a material different from a material of the polymer layer.

According to some implementations of the present disclosure, a semiconductor package may comprise: a package substrate; a plurality of semiconductor dies stacked on the package substrate and in contact with each other, wherein end portions of the semiconductor dies form a stepwise shape; a plurality of wires that connect the semiconductor dies to the package substrate; an adhesion film between the package substrate and a lowermost one of the semiconductor dies; a mold layer that covers the package substrate, the semiconductor dies, and the wires; and a plurality of external connection terminals bonded to a bottom surface of the package substrate. Each of the semiconductor dies may include: a die substrate; a die dielectric layer on the die substrate; a bonding pad on the die dielectric layer; and a polymer layer that covers the die dielectric layer and exposes the bonding pad. The polymer layer may have a first thickness. The adhesion film may have a second thickness different from the first thickness.

According to some implementations of the present disclosure, a method of fabricating a semiconductor package may comprise: preparing a first wafer that includes a plurality of device regions and a separation region between the device regions; forming a plurality of conductive pads on the device regions; forming a polymer layer on the first wafer; using a mask pattern to etch the polymer layer and to expose the conductive pads; cutting the separation region of the first wafer to manufacture a first semiconductor die and a second semiconductor die; forming a hydroxyl group on the polymer layer of the first semiconductor die; forming a hydroxyl group on a bottom surface of the second semiconductor die; placing the second semiconductor die on the first semiconductor die; and performing a thermocompression process to bond the second semiconductor die onto the first semiconductor die.

### BRIEF DESCRIPTION OF DRAWINGS

FIG. 1 is a cross-sectional view illustrating an example of a semiconductor package concepts.

FIGS. 2A and 2B illustrate enlarged views of section P1 of FIG. 1.

FIG. 2C illustrates an enlarged view of section P2 of FIG. 1.

FIG. 3 is a cross-sectional view illustrating an example of a semiconductor package.

FIGS. 4A to 4N are cross-sectional views illustrating a method of fabricating the semiconductor package depicted in FIG. 1.

FIGS. 5A to 5E are cross-sectional views illustrating a method of fabricating the semiconductor package depicted in FIG. 1.

FIG. 6 is a cross-sectional view illustrating an example of a semiconductor package.

FIG. 7 is a cross-sectional view illustrating an example of a semiconductor package.

### DETAILED DESCRIPTION

Some implementations will now be described in detail with reference to the accompanying drawings to aid in clearly explaining the present disclosure. In this description, such terms as “first” and “second” may be used to simply distinguish identical or similar components from each other, and the sequence of such terms may be changed in accordance with the order of mention.

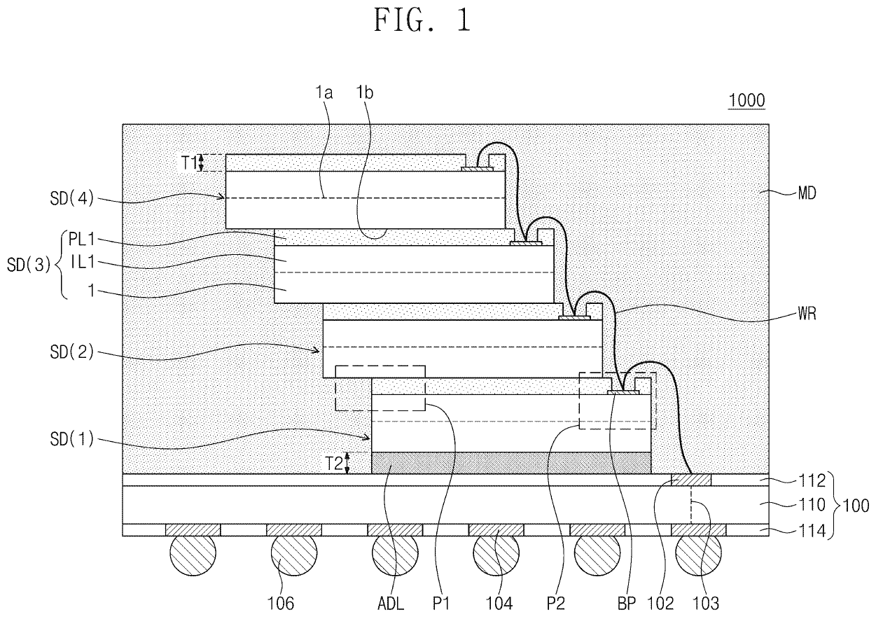

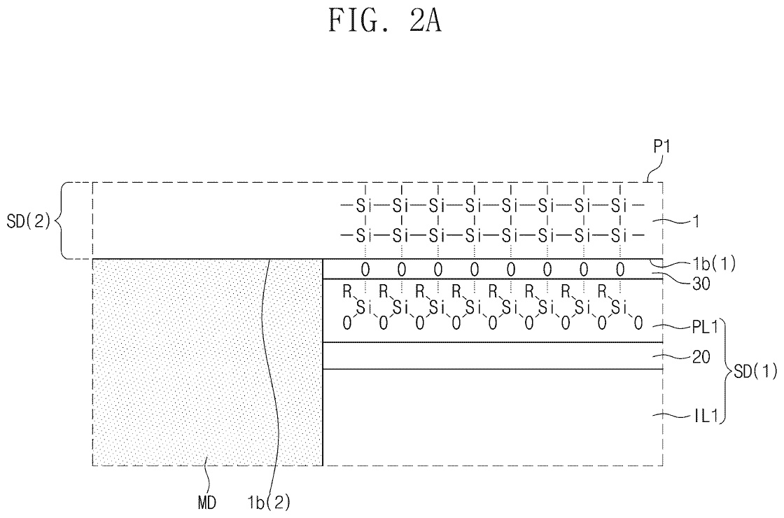

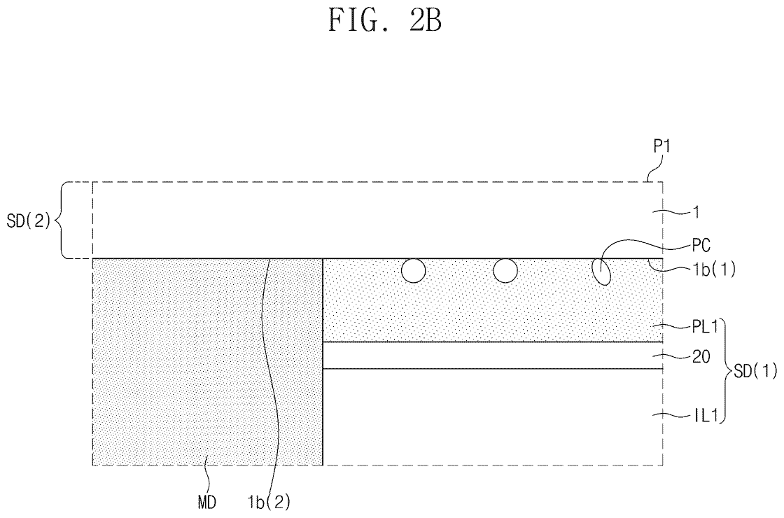

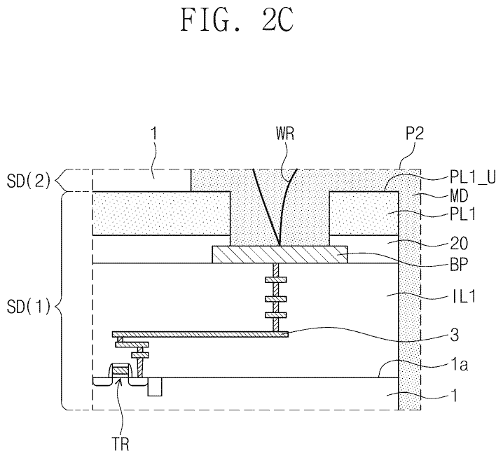

FIG. 1 is a cross-sectional view illustrating an example of a semiconductor package according to some implementations of the present disclosure. FIGS. 2A and 2B are enlarged views showing section P1 of FIG. 1. FIG. 2C is an enlarged view showing section P2 of FIG. 1.

Referring to FIGS. 1 and 2A to 2C, a semiconductor package 1000 may include a package substrate 100, semiconductor dies SD, and a mold layer MD. The package substrate 100 may be, for example, a double-side or multi-layered printed circuit board. The package substrate 100 may include a body layer 110, upper conductive pads 102 disposed on a top surface of the body layer 110, an upper dielectric layer 112 that covers the top surface of the body layer 110, ball lands 104 disposed on a bottom surface of the body layer 110, and a lower dielectric layer 114 that covers the bottom surface of the body layer 110. The body layer 110 may include one or more of a thermosetting resin such as epoxy resin, a thermoplastic resin such as polyimide, a resin in which a thermosetting or thermoplastic resin is impregnated with a reinforcement such as glass fiber and/or inorganic filler (which impregnated resin includes a prepreg or a fire resist-4 (FR4)), and a photosensitive resin, but the body layer is not limited thereto.

Each of the upper and lower dielectric layers 112 and 114 may be a photosensitive solder resist (PSR) layer. The upper conductive pads 102 and the ball lands 104 may include, for example, copper. The body layer 110 may be provided therein with internal wiring lines 103 that electrically connect the upper conductive pads 102 to the ball lands 104. The internal wiring lines 103 may include vias.

Although the package substrate 100 is described as a printed circuit board, the present disclosure is not limited thereto and the package substrate 100 may be, for example, a redistribution substrate. In this case, the package substrate 100 may include sequentially stacked redistribution dielectric layers and redistribution patterns disposed in the redistribution dielectric layers. Each of the redistribution dielectric layers may be formed of a photo-imageable dielectric (PID) layer. The redistribution patterns may include metal, such as copper.

External connection terminals 106 may be bonded to the ball lands 104. The external connection terminals 106 may include at least one of solder balls, conductive bumps, and conductive pillars. The external connection terminals 106 may include at least one selected from tin, lead, silver, aluminum, copper, gold, and nickel.

The semiconductor dies SD may be sequentially stacked on the package substrate 100. End portions of the semiconductor dies SD may form a stepwise shape. The semiconductor die SD may be called a semiconductor chip. Neighboring semiconductor dies SD may be in direct contact with and bonded to each other. The semiconductor dies SD may be the same memory chip. For example, the semiconductor dies SD may be a Flash memory chip, a dynamic random access memory (DRAM) chip, a static random access memory (SRAM) chip, an electrically erasable programmable read-only memory (EEPROM) chip, a phase change random access memory (PRAM) chip, a magnetic random access memory (MRAM) chip, or a resistive random access memory (ReRAM) chip. In the present disclosure, although four semiconductor dies SD are illustrated, the number of semiconductor dies is not limited thereto and the number of the semiconductor dies SD may be equal to or greater than five or equal to or less than three.

Each of the semiconductor dies SD may include a die substrate 1, a die dielectric layer IL1, a bonding pad BP, and a first polymer layer PL1. The die substrate 1 may include at least one selected from a semiconductor material such as silicon or a dielectric material such as silicon oxide. The die substrate 1 may have a front surface 1a and a rear surface 1b. The die substrate 1 may be provided on its front surface 1a with transistors TR, capacitors, memory cells, and wiring lines 3, which components may constitute various integrated circuits.

The front surface 1a of the die substrate 1 may be covered with the die dielectric layer IL1. The die dielectric layer IL1 may have a single-layered or multi-layered structure of at least one selected from SiO₂, SiN, SiON, SiCN, and SiOCN. The bonding pad BP may be disposed on the die dielectric layer IL1. The bonding pad BP may include metal, such as copper or aluminum.

The first polymer layer PL1 may be disposed on the die dielectric layer IL1. The first polymer layer PL1, as shown in FIG. 1, may be in contact with a top surface of the die dielectric layer IL1. Alternatively, a protection layer 20 (shown in FIG. 2A) may be interposed between the first polymer layer PL1 and the die dielectric layer IL1. The protection layer 20 may be formed of, for example, SiN or SiCN. The first polymer layer PL1 may expose the bonding pad BP. A sidewall of the first polymer layer PLI may be aligned with that of the protection layer 20.

The first polymer layer PL1 may be formed of a polymer. The first polymer layer PL1 may have a polymer chain structure as shown in FIG. 2A. A backbone of the polymer included in the first polymer layer PL1 may include at least one selected from silicon (atoms) and carbon (atoms). A functional group R connected to the backbone of the polymer may be, for example, a C1 to C10 alkyl or alkenyl group. The functional group R may be, for example, a methyl group. The first polymer layer PL1 may be formed of polydimethylsiloxane (PDMS). The first polymer layer PL1 may include no photosensitive material.

Oxygen atoms may be interposed between the semiconductor dies SD, and may provide an oxide bonding between the semiconductor dies SD. In this sense, an oxide bonding may be accomplished between the semiconductor dies SD that are adjacent to each other. For example, an oxide bonding may be present between a top surface of the first polymer layer PL1 included in a lower one among neighboring semiconductor dies SD and the rear surface 1b of the die substrate 1 of the semiconductor die SD included in an upper one among neighboring semiconductor dies SD.

The semiconductor dies SD may include first to fourth semiconductor dies SD(1) to SD (4) that are sequentially stacked upwards. For example, oxygen atoms may be interposed between silicon atoms in the first polymer layer PL1 of the first semiconductor die SD(1) and silicon atoms in the die substrate 1 of the second semiconductor die SD(2) that overlies the first semiconductor die SD(1), thereby bonding the first semiconductor die SD(1) and the second semiconductor die SD(2). The oxygen atoms may be called an oxide layer 30. The oxide bonding may be a covalent bond that provides a very strong bonding force between the semiconductor dies SD. Thus, it may be possible to prevent non-adhesion or crack between the semiconductor dies SD and to improve reliability of the semiconductor package 1000.

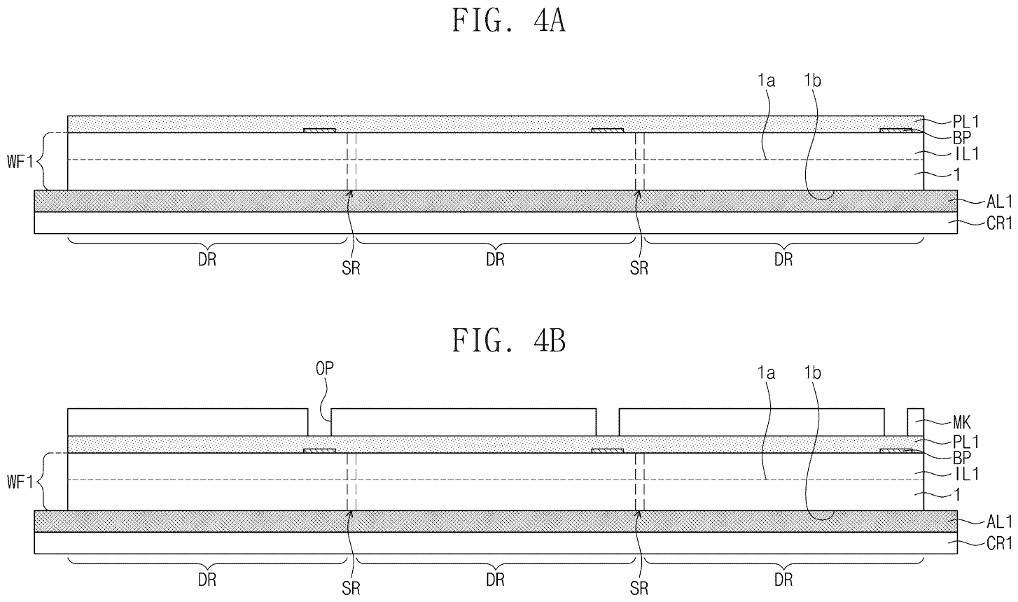

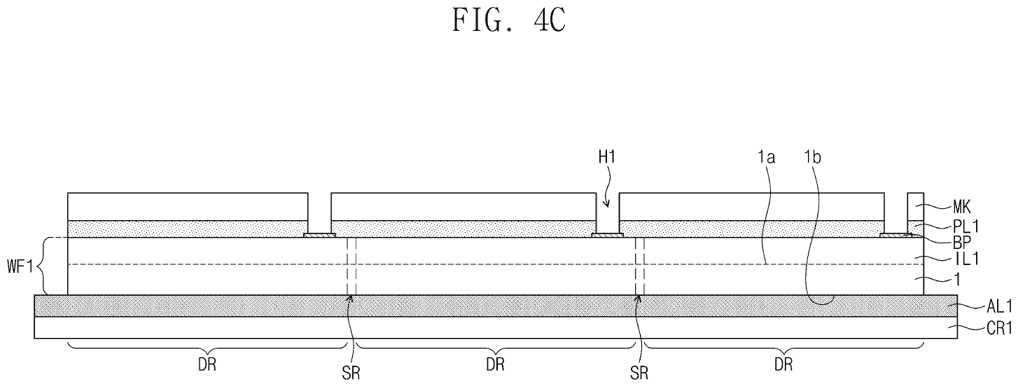

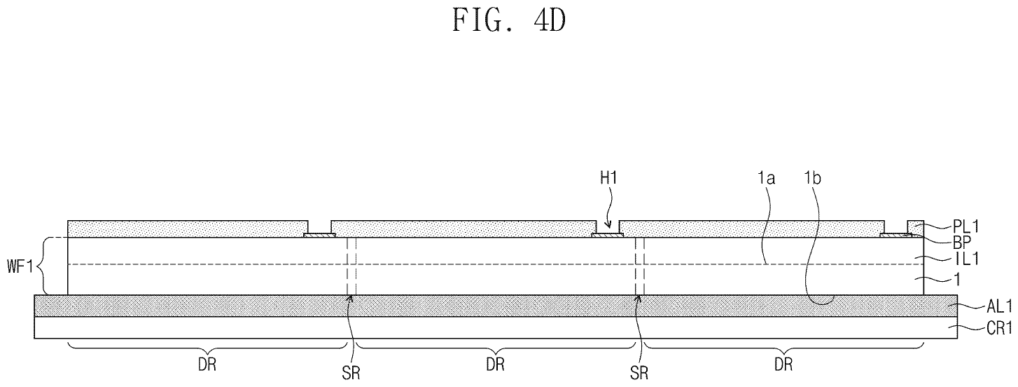

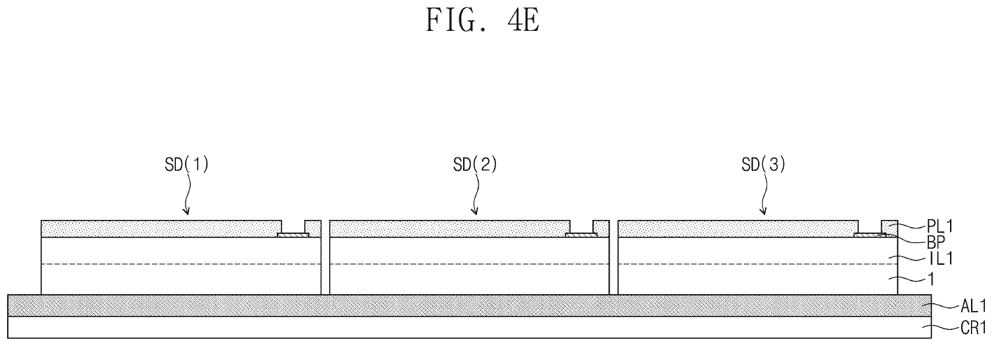

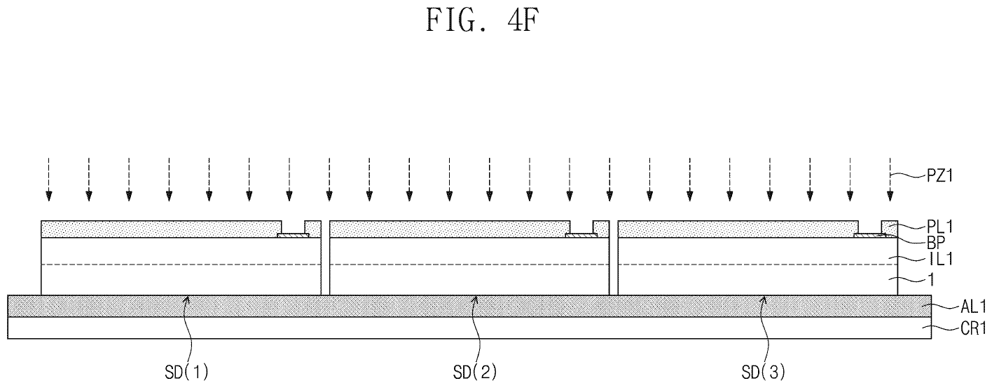

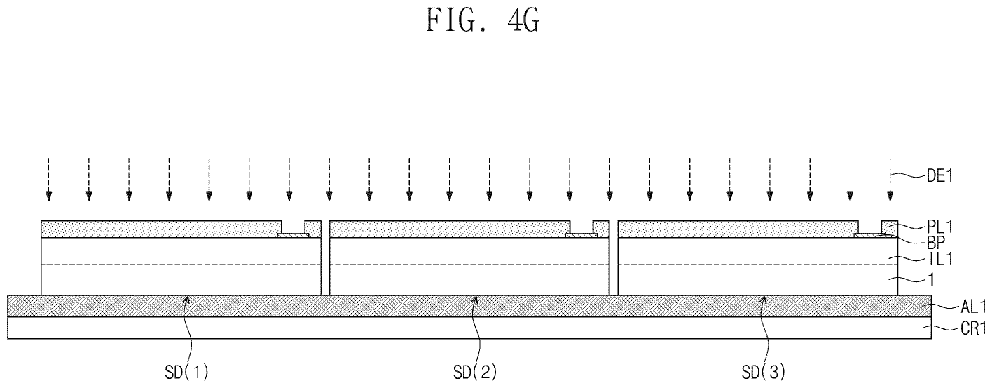

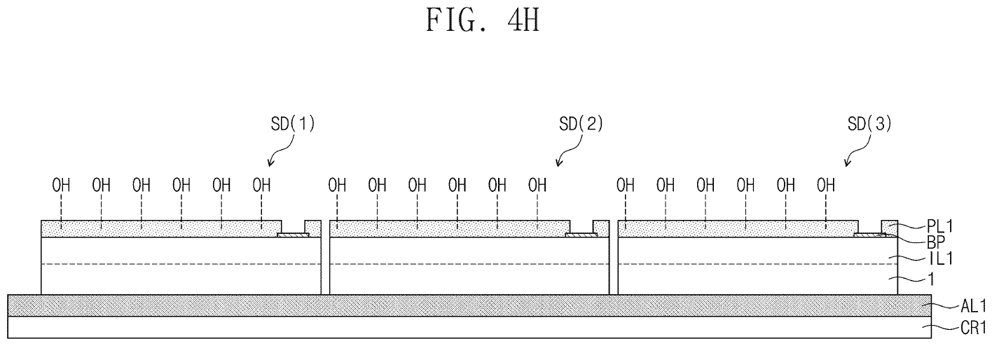

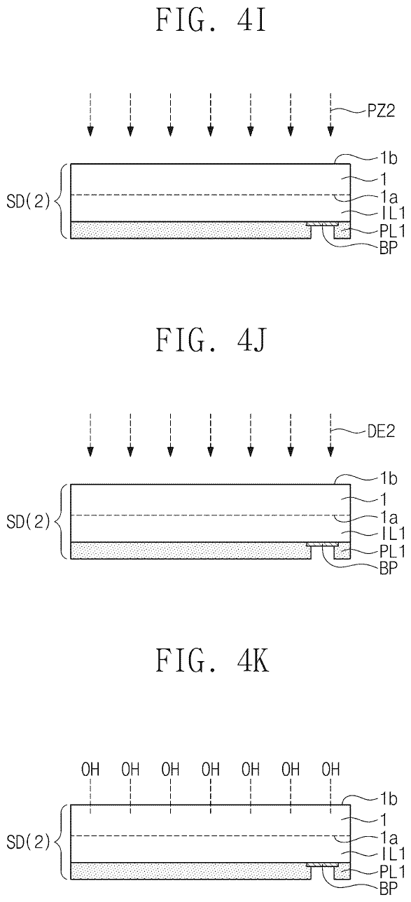

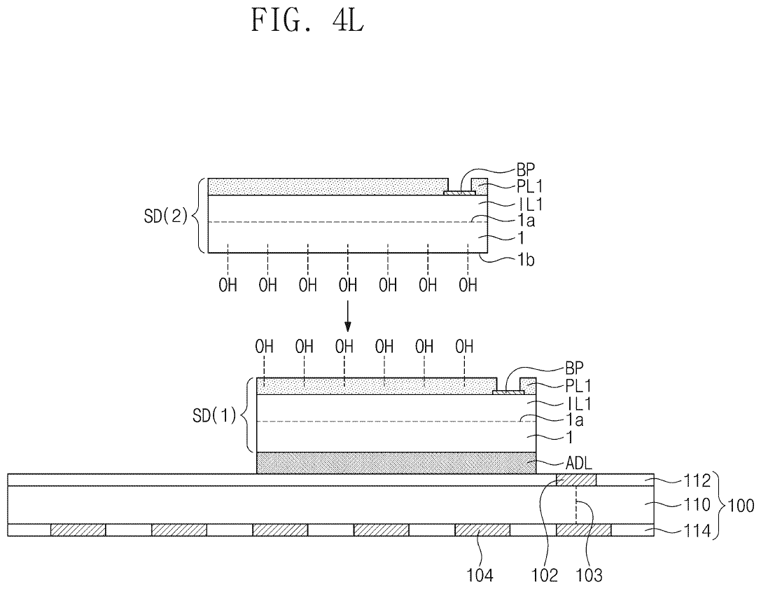

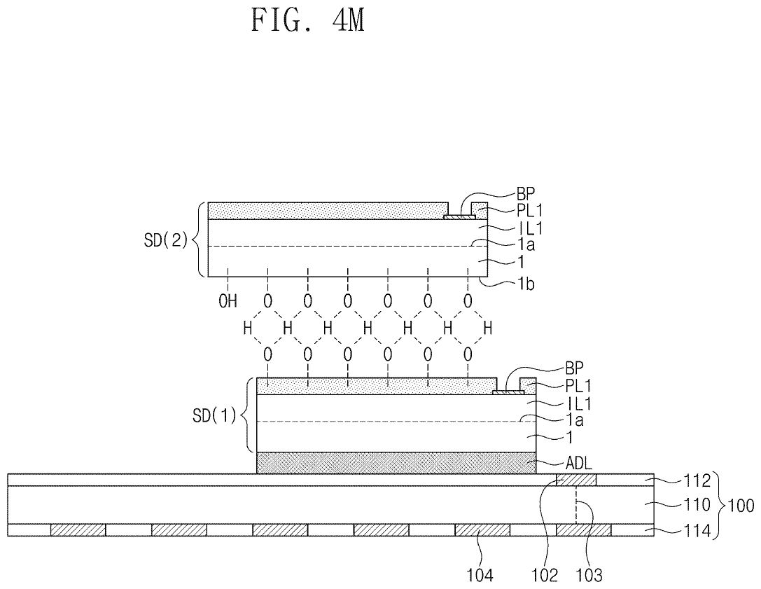

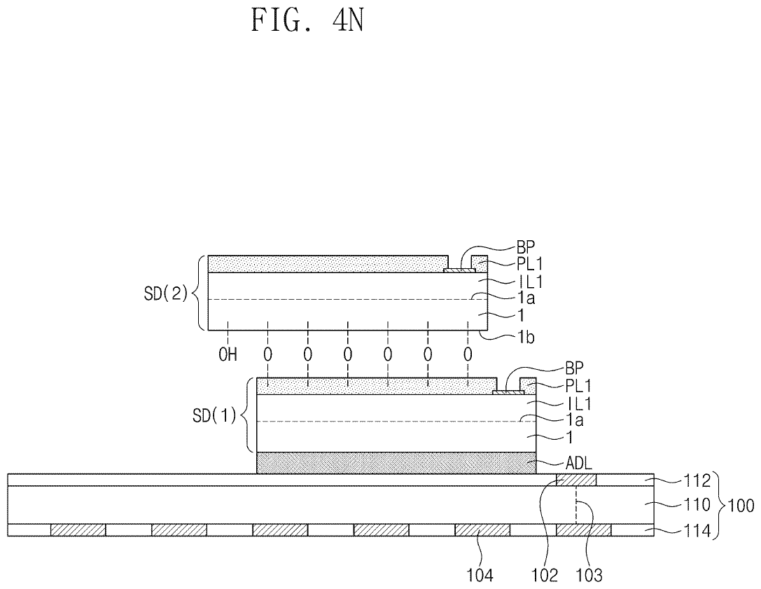

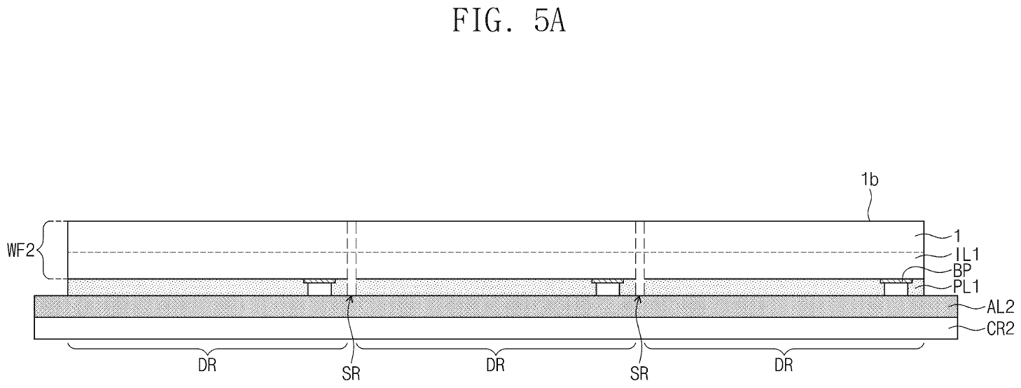

The rear surface 1b of the die substrate 1 may include a first region 1b(1) in contact with the semiconductor die SD that underlies the die substrate 1 and a second region 1b(2) in contact with the mold layer MD that underlies the die substrate 1. Although not shown in FIG. 2A, a hydroxyl group may remain or an oxide layer may be formed on the second region 1b(2) of the rear surface 1b of the die substrate 1 as illustrated in FIG. 4N.

Although not shown, a hydroxyl group may remain or an oxide layer may be formed on the top surface PL1_U of the first polymer layer PL1, which top surface PL1_U is exposed without being in contact with the semiconductor die SD.

In the semiconductor package 1000 according to some implementations, no adhesion film may be interposed between semiconductor dies having their respective stack structures. The adhesion film (which is not present) may therefore not contribute to an increase in stack height of the semiconductor dies, and thus there may be a reduction in overall height of the semiconductor dies. Accordingly, the semiconductor package 1000 may decrease in size.

Referring to FIG. 2B, according to some implementations, particles PC may be interposed between the semiconductor dies SD. Each of the particles PC may be formed of at least one selected from SiO₂, SiN, SiCN, Si, and metal. The particles PC may be positioned in an upper portion of an adjacent first polymer layer PL1 between the semiconductor dies SD. The first polymer layer PL1 may exhibit elasticity greater than that of an inorganic layer such as a silicon oxide layer or a silicon carbonitride (SiCN) layer. The first polymer layer PL1 may exhibit plasticity greater than that of an inorganic layer such as a silicon oxide layer or a silicon carbonitride (SiCN) layer. The first polymer layer PL1 may be stretched and deformed more easily than an inorganic layer. Therefore, the first polymer layer PL1 may receive therein the particles PC interposed between the semiconductor dies SD during their stacking and bonding. The particles PC may have different shapes and sizes. The particles PC may be in contact with the rear surface 1b of the die substrate 1 of the semiconductor die SD that overlies the particles PC.

An adhesion film ADL may be interposed between the package substrate 100 and the first semiconductor die SD(1) or a lowermost one of the semiconductor dies SD. The adhesion film ADL may have a different material from that of the first polymer layer PL1. For example, the adhesion film ADL may include an epoxy. The adhesion film ADL may not include silicon. The first polymer layer PL1 may have a first thickness T1. The adhesion film ADL may have a second thickness T2 different from the first thickness T1. For example, the second thickness T2 may be greater than the first thickness T1.

Wires WR may contact and electrically connect the bonding pads BP of the semiconductor dies SD and the upper conductive pads 102 of the package substrate 100. The wires WR may include metal, such as gold and/or copper. The mold layer MD may cover the semiconductor dies SD, the wires WR, and the package substrate 100. The mold layer MD may include a dielectric resin, such as an epoxy molding compound (EMC). The mold layer MD may further include fillers, and the fillers may be dispersed in the dielectric resin.

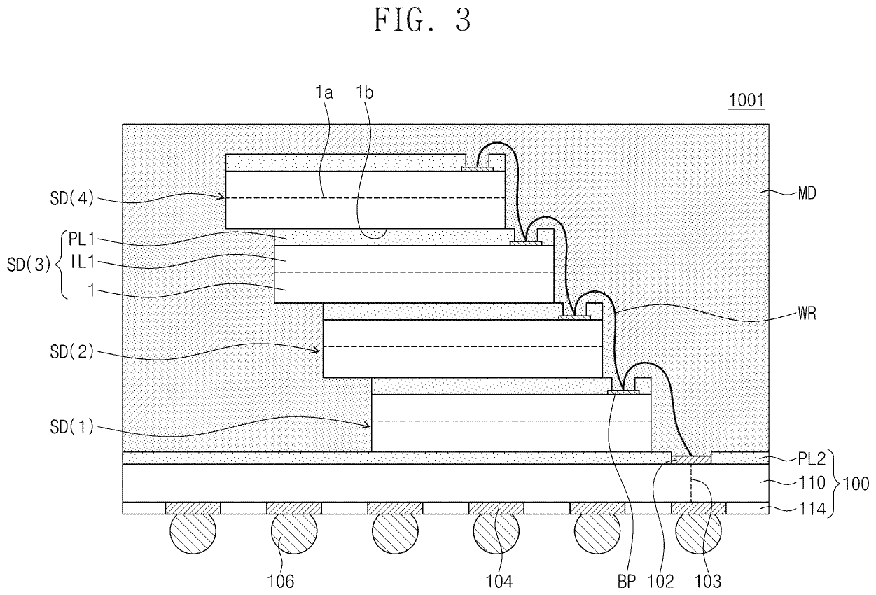

FIG. 3 is a cross-sectional view showing a semiconductor package according to some implementations of the present disclosure.

Referring to FIG. 3, in a semiconductor package 1001, the top surface of the body layer 110 of the package substrate 100 may be covered with a second polymer layer PL2 in place of the upper dielectric layer 112 depicted in FIG. 1. The second polymer layer PL2 may expose the upper conductive pads 102. Oxygen atoms may be interposed between a top surface of the second polymer layer PL2 of the package substrate 100 and a bottom surface of the die substrate 1 of the first semiconductor die SD(1) (e.g., as described with respect to FIG. 2A), thereby providing an oxide bonding between the package substrate 100 and the first semiconductor die SD(1). The adhesion film ADL of FIG. 1 may not be interposed between the first semiconductor die SD(1) and the package substrate 100, and thus there may be a reduction in vertical height of the semiconductor package 1001.

FIGS. 4A to 4N illustrate cross-sectional views showing an example of a method of fabricating the semiconductor package depicted in FIG. 1.

Referring to FIG. 4A, a first wafer WF1 may be bonded through a first bonding layer AL1 to a first carrier substrate CR1. The first carrier substrate CR1 may be, for example, a glass substrate. Alternatively, a tape may be used as the first carrier substrate CR1 to which the first bonding layer AL1 is attached. The first bonding layer AL1 may include a single-layered or multi-layered adhesion film and/or a single-layered or multi-layered relieving layer. The first wafer WF1 may include a die substrate 1 and a die dielectric layer IL1 on the die substrate 1. The die substrate 1 may include device regions DR and a separation region SR between the device regions DR. The separation region SR may be a scribe lane region. In each of the device regions DR, the die substrate 1 may be provided thereon with transistors TR, capacitors, memory cells, and wiring lines 3, which components may constitute various integrated circuits. In each of the device regions DR, bonding pads BP may be formed on the die dielectric layer IL1. A first polymer layer PL1 may be formed on the die dielectric layer IL1. The first polymer layer PL1 may be formed by coating and curing processes. The first polymer layer PL1 in a coated state before the curing process may be in A-stage.

For example, the curing process may be performed at a temperature of about 150° C. to about 250° C., and may allow the first polymer layer PL1 to reach C-stage. The first polymer layer PL1 may be formed of, for example, polydimethylsiloxane (PDMS). The first polymer layer PL1 may include no photosensitive material. The formation of the first polymer layer PL1 may be preceded by the formation of a protection layer 20 depicted in FIGS. 2A to 2C. The protection layer 20 may be formed of, for example, SiN or SiCN. The first polymer layer PL1 may serve to protect the die dielectric layer IL1.

Referring to FIG. 4B, a mask pattern MK may be formed on the first polymer layer PL1. The mask pattern MK may have openings OP that overlap the bonding pads BP. The mask pattern MK may be, for example, a photoresist pattern.

Referring to FIG. 4C, the mask pattern MK may be used as an etching mask to etch the first polymer layer PLI to form holes H1 that expose the bonding pads BP. When the first polymer layer PLI is etched, the protection layer 20 may also be etched.

Referring to FIG. 4D, the mask pattern MK may be removed to expose a top surface of the first polymer layer PL1.

Referring to FIG. 4E, a laser or a blade may be used to allow the first wafer WF1 to undergo a chip singulation process or a dicing process to remove the separation region SR and to leave only the device regions DR, thereby manufacturing a plurality of semiconductor dies SD. The semiconductor dies SD may be attached to the first carrier substrate CR1 through the first bonding layer AL1 on the first carrier substrate CR1.

A procedure depicted in FIGS. 4F and 4G may be carried out to perform a surface activation of the first polymer layer PL1. For example, referring to FIG. 4F, a first plasma treatment process PZ1 may be performed on the top surface of the first polymer layer PL1. For example, oxygen may be used to perform the first plasma treatment process PZ1. The first plasma treatment process PZ1 may form a dangling bond by partially removing a functional group connected to a backbone of the first polymer layer PL1.

Referring to FIGS. 4G and 4H, the top surface of the first polymer layer PL1 may undergo a first deionized water treatment process DE1. Thus, a hydroxyl group (—OH) of the deionized water may be combined with the dangling bond, such that the hydroxyl group may be bonded to the top surface of the first polymer layer PL1. Accordingly, the top surface of the first polymer layer PL1 may be activated. The surface activation may cause the top surface of the first polymer layer PL1 to exhibit adhesiveness.

Referring to FIG. 41, the semiconductor dies SD may be separated from the first bonding layer AL1. One or more of the semiconductor dies SD may be turned upside down. For example, a second semiconductor die SD(2) may be overturned to allow a rear surface 1b of the die substrate 1 to face upwards. A surface activation may be performed on the rear surface 1b of the die substrate 1. For example, a second plasma treatment process PZ2 may be performed on the rear surface 1b of the die substrate 1. For example, oxygen may be used to perform the second plasma treatment process PZ2. The second plasma treatment process PZ2 may form a dangling bond on silicon atoms included in the die substrate 1.

Referring to FIGS. 4J and 4K, a second deionized water treatment process DE2 may be performed on the rear surface 1b of the die substrate 1. Thus, a hydroxyl group (—OH) of the deionized water may be combined with the dangling bond, such that the hydroxyl group may be bonded to the rear surface 1b of the die substrate 1. Accordingly, the rear surface 1b of the die substrate 1 may be activated.

Referring to FIGS. 4L and 4M, a first semiconductor die SD(1) including the first polymer layer PL1 whose top surface has a hydroxyl group (—OH) formed thereon may be bonded through an adhesion film ADL to a package substrate 100. The first semiconductor die SD(1) may be provided thereon with the second semiconductor die SD(2) including the die substrate 1 whose rear surface 1b has a hydroxyl group (—OH) formed thereon. In this case, as a hydrogen bond may be formed between the hydroxyl group (—OH) on an upper portion of the first semiconductor die SD(1) and the hydroxyl group (—OH) on a lower portion of the second semiconductor die SD(2), an adhesive force may be achieved at room temperature. Hence, semiconductor dies such as the first to fourth semiconductor dies SD(1) to SD(2) may be stacked at room temperature as shown in FIG. 1.

Referring to FIGS. 4M and 4N, an annealing process may be performed such that a water molecule may escape from the hydroxyl groups that are connected through the hydrogen bond between the semiconductor dies SD, and thus only oxygen atoms may remain and the hydrogen bond may be converted into an oxide bond that is a covalent bond. The annealing process may be performed at a temperature of about 200° C. to about 500° C. Accordingly, the semiconductor dies SD may be combined through an oxide bond without an adhesive. During the annealing process, a pressure may be applied to the semiconductor dies SD. The annealing process may be called a thermal compression process.

Particles (see PC of FIG. 2B) may occur in the chip singulation process or the dicing process of FIG. 4E. Each of the particles PC may be formed of at least one selected from SiO₂, SiN, SiCN, Si, and metal. The particles PC may be eliminated in the first deionized water treatment process DE1 of FIG. 4G and/or the second deionized water treatment DE2 of FIG. 4K. Hence, process defects may be reduced.

If some of the particles PC remain in the deionized water treatment processes DE1 and DE2 of FIGS. 4G and 4J, the particles PC may be interposed between the semiconductor dies SD when the semiconductor dies SD are stacked and bonded as shown in FIGS. 4L to 4N. The first polymer layer PL1 may exhibit elasticity greater than that of an inorganic layer such as a silicon oxide layer or a silicon carbonitride (SiCN) layer. The first polymer layer PL1 may exhibit plasticity greater than that of an inorganic layer such as a silicon oxide layer or a silicon carbonitride (SiCN) layer. The first polymer layer PL1 may be stretched and deformed more easily than an inorganic layer. For example, as the first polymer layer PL1 is soft, the particles PC may migrate into the first polymer layer PL1.

When the first polymer layer PLI is as hard as an inorganic layer, non-adhesion and/or crack may occur due to the particles PC during the bonding process of the semiconductor dies SD, thereby leading to defects of a semiconductor package. In contrast, according to some implementations herein, aforementioned characteristics of the first polymer layer PL1 may be caused to prevent defects of a semiconductor package. As a result, fabrication yield may increase. After the bonding of the semiconductor dies SD, wires WR and a mold layer MD may be formed as illustrated in FIG. 1.

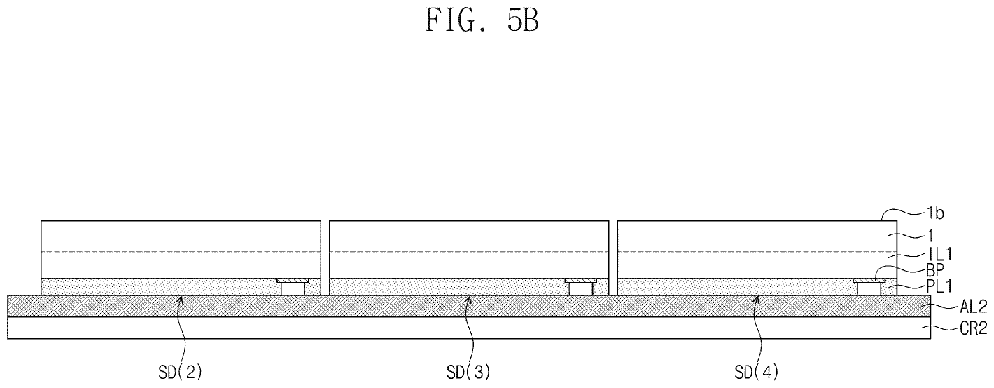

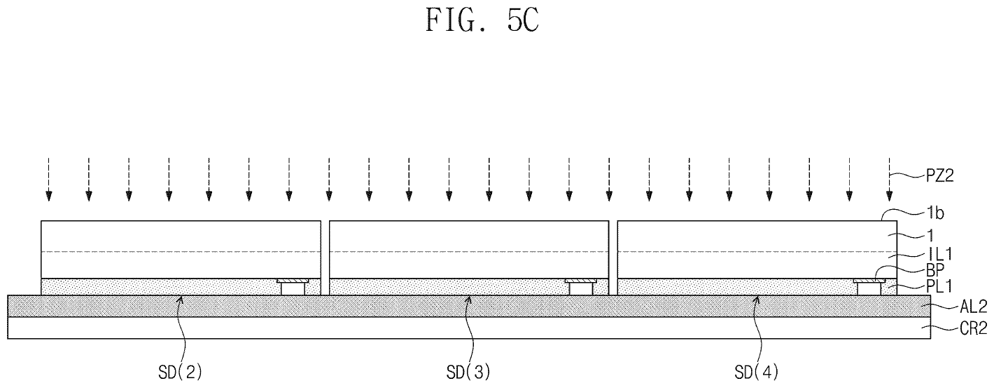

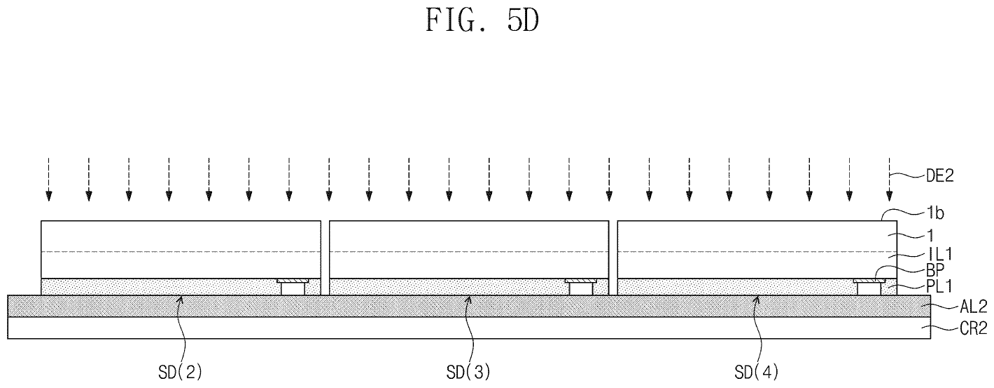

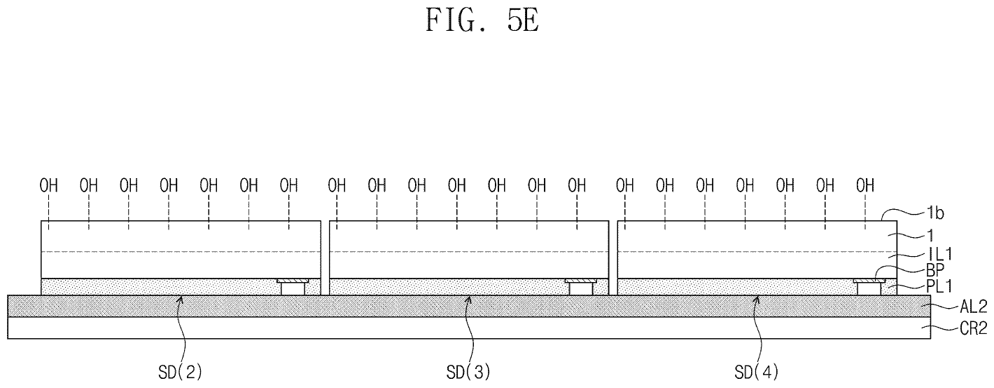

FIGS. 5A to 5E illustrate cross-sectional views showing an example of a method of fabricating the semiconductor package depicted in FIG. 1.

Referring to FIG. 5A, the method of FIGS. 4A to 4D may be used to form a first polymer layer PL1 on a second wafer WF2. In a state where the second wafer WF2 is turned upside down to allow the first polymer layer PL1 to face downwards, the second wafer WF2 may be bonded through a second bonding layer AL2 to a second carrier substrate CR2. Thus, the second bonding layer AL2 may be in contact with the first polymer layer PL1, and a rear surface 1b of the second wafer WF2 may be directed upwards.

Referring to FIG. 5B, a laser or a blade may be used to allow the second wafer WF2 to undergo a chip singulation process or a dicing process to remove the separation region SR and to leave only the device regions DR, thereby manufacturing a plurality of semiconductor dies SD. The semiconductor dies SD may be attached to the second carrier substrate CR2 through the second bonding layer AL2 on the second carrier substrate CR2.

Referring to FIGS. 5C and 5D, a surface activation may be performed on the rear surface 1b of the die substrate 1 of the semiconductor dies SD. For example, a second plasma treatment process PZ2 may be performed on the rear surface 1b of the die substrate 1. For example, oxygen may be used to perform the second plasma treatment process PZ2. The second plasma treatment process PZ2 may form a dangling bond on silicon atoms included in the die substrate 1.

Referring to FIGS. 5D and 5E, a second deionized water treatment process DE2 may be performed on the rear surface 1b of the die substrate 1. Thus, a hydroxyl group (—OH) of the deionized water may be combined with the dangling bond, such that the hydroxyl group may be bonded to the rear surface 1b of the die substrate 1. Accordingly, the rear surface 1b of the die substrate 1 may be activated.

Referring back to FIGS. 4L and 4M, a first semiconductor die SD(1) including the first polymer layer PL1 whose top surface has a hydroxyl group (—OH) formed thereon may be bonded through an adhesion film ADL to a package substrate 100. The first semiconductor die SD(1) may be provided thereon with a second semiconductor die SD(2) including the die substrate 1 whose bottom surface 1b has a hydroxyl group (—OH) of FIG. 5E formed thereon. An annealing process may be performed to bond the semiconductor dies SD.

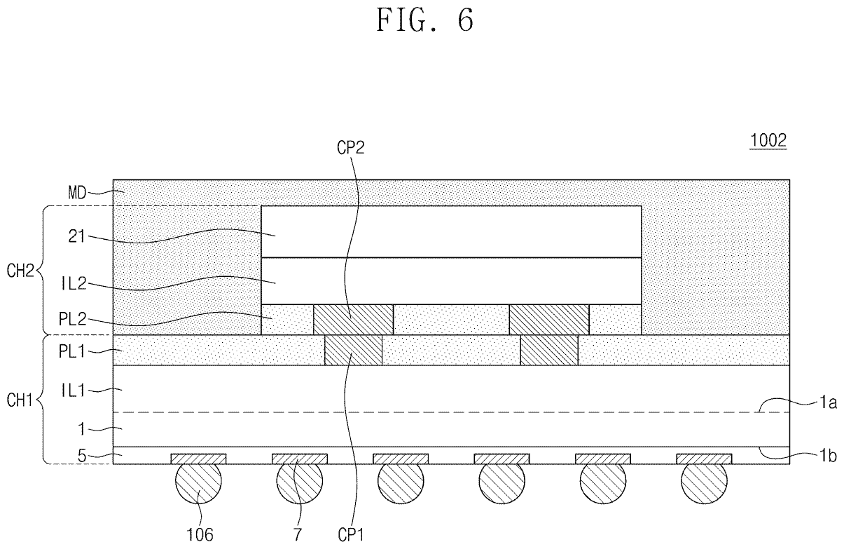

FIG. 6 illustrates a cross-sectional view showing a semiconductor package according to some implementations of the present disclosure.

Referring to FIG. 6, a semiconductor package 1002 may include a first semiconductor chip CH1, a second semiconductor chip CH2, and a mold layer MD that are sequentially stacked. The first semiconductor chip CH1 may have a width greater than that of the second semiconductor chip CH2. The first semiconductor chip CH1 may include a first die substrate 1, and may also include a first die dielectric layer IL1 and a first polymer layer PL1 that are sequentially stacked on a front surface 1a of the first die substrate 1. First connection pads CP1 may be disposed on the first die dielectric layer IL1. The first polymer layer PL1 may expose the first connection pads CP1. Transistors and wiring lines may be disposed on the front surface 1a of the first die substrate 1. A rear surface 1b of the first die substrate 1 may be covered with a lower dielectric layer 5. Lower conductive pads 7 may be disposed in the lower dielectric layer 5. The first semiconductor chip CH1 may further include through vias that connect the lower conductive pads 7 to the first connection pads CP1. The first connection pads CP1 and the lower conductive pads 7 may include metal, such as copper. External connection terminals 106 may be bonded to the lower conductive pads 7. The external connection terminals 106 may include at least one of solder balls, conductive bumps, and conductive pillars.

The second semiconductor chip CH2 may include a second die substrate 21, and may also include a second die dielectric layer IL2 and a second polymer layer PL2 that are disposed on a bottom surface of the second die substrate 21. Second connection pads CP2 may be disposed below the second die dielectric layer IL2. The second polymer layer PL2 may expose the second connection pads CP2. Transistors and wiring lines may be disposed on the bottom surface of the second die substrate 21. A top surface of the second die substrate 21 may be covered with the mold layer MD.

The second connection pads CP2 may be correspondingly in contact with the first connection pads CP1. The second connection pads CP2 may include metal, such as copper. The second connection pads CP2 may have their widths different from those of the first connection pads CP1. For example, the widths of the second connection pads CP2 may be greater than those of the first connection pads CP1. The second connection pad CP2 and the first connection pad CP1 in contact with each other may be connected into a single unitary piece without a boundary therebetween.

A bottom surface of the second polymer layer PL2 may be in contact with a top surface of the first polymer layer PL1. Oxygen atoms may be interposed, as shown in FIG. 2A, between the second polymer layer PL2 and the first polymer layer PL1, thereby forming an oxide layer 30. An oxide bond may be provided between the second polymer layer PL2 and the first polymer layer PL1. Other configurations may be identical or similar to those discussed above.

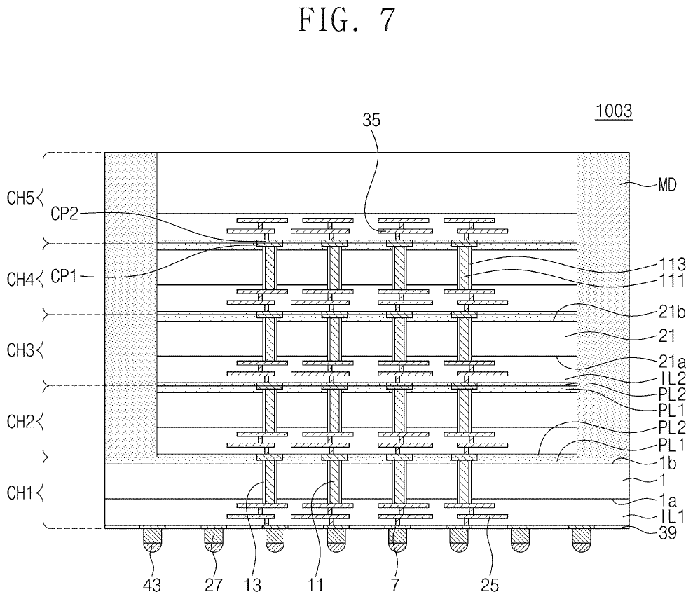

FIG. 7 illustrates a cross-sectional view showing an example of a semiconductor package according to some implementations of the present disclosure.

Referring to FIG. 7, a semiconductor package 1003 may include sequentially stacked first to fifth semiconductor chips CH1 to CH5 and a mold layer MD. Each of the first to fifth semiconductor chips CH1 to CH5 may be called a semiconductor die. The first semiconductor chip CH1 may have a width greater than those of the second to fifth semiconductor chips CH2 to CH5. The first semiconductor chip CH1 may be a buffer die or a logic die.

The second to fifth semiconductor chips CH2 to CH5 may be the same memory chip. Each of the second to fifth semiconductor chips CH2 to CH5 may be a Flash memory chip, a dynamic random access memory (DRAM) chip, a static random access memory (SRAM) chip, an electrically erasable programmable read-only memory (EEPROM) chip, a phase change random access memory (PRAM) chip, a magnetic random access memory (MRAM) chip, or a resistive random access memory (ReRAM) chip. The semiconductor package 1003 in the example of FIG. 7 has a structure in which four memory dies CH2 to CH5 are stacked on one buffer die CH1, but the configuration is not limited thereto. For example, the semiconductor package 1003 may have a structure in which are stacked three or less memory dies or five or more memory dies.

The first semiconductor chip CH1 may include a first die substrate 1. A front surface 1a of the first die substrate 1 may be covered with a first die dielectric layer IL1 and a first protection layer 39 that are sequentially stacked. First transistors and first wiring lines 25 may be disposed on the front surface 1a of the first die substrate 1. Lower conductive pads 7 may be disposed in a lower portion of the first die dielectric layer IL1. Conductive bumps 27 may be correspondingly bonded to the lower conductive pads 7. Solder layers 43 may be correspondingly bonded to the conductive bumps 27.

A rear surface 1b of the first die substrate 1 may be covered with a first polymer layer PL1. First connection pads CP1 may be disposed in the first polymer layer PL1. First through vias 11 may penetrate the first die substrate 1 to connect the first connection pads CP1 to the first wiring lines 25. A first via dielectric layer 13 may be interposed between the first through via 11 and the first die substrate 1.

Each of the second to fifth semiconductor chips CH2 to CH5 may include a second die substrate 21. A front surface 21a of the second die substrate 21 may be covered with a second die dielectric layer IL2 and a second polymer layer PL2 that are sequentially stacked. Second transistors and second wiring lines 35 may be disposed on the front surface 21a of the second die substrate 21. Second connection pads CP2 may be disposed below the second die dielectric layer IL2.

In the second to fourth semiconductor chips CH2 to CH4, a rear surface 21b of the second die substrate 21 may be covered with a first polymer layer PL1. First connection pads CP1 may be disposed in the first polymer layer PL1. Each of the second to fourth semiconductor chips CH2 to CH4 may further include a second through via 111 and a second via dielectric layer 113 that penetrate the second die substrate 21. The second die substrate 21 of the fifth semiconductor chip CH5 may have a top surface that is exposed without being covered with the mold layer MD.

In the semiconductor package 1003, an oxide bond may be provided between the first to fifth semiconductor chips CH1 to CH5. Oxygen atoms may be present between a top surface of the first polymer layer PL1 and a bottom surface of the second polymer layer PL2, thereby providing an oxide bond between the first polymer layer PL1 and the second polymer layer PL2. The first connection pads CP1 may be in contact with the second connection pads CP2 that are adjacent thereto. Other configurations may be identical or similar to those discussed above.

Accordingly, an oxide bond may be provided between stacked semiconductor dies, and thus a bonding force between the semiconductor dies may become strong to prevent non-adhesion or crack between the semiconductor dies and to improve reliability. In addition, no adhesion film may be interposed between the semiconductor dies. Each of the semiconductor dies may not include photosensitive polyimide (PSPI) that is a type of photosensitive dielectric layer. Accordingly, it may be possible to reduce a stack height of the semiconductor dies and to decrease a size of the semiconductor package.

In a method of fabricating a semiconductor package, an oxide bond may be provided between semiconductor dies to increase a bonding force between the semiconductor dies, thereby reducing or preventing defects. Moreover, since a polymer layer disposed on an upper portion of each of semiconductor dies has elasticity/plasticity greater than that of an inorganic layer, the polymer layer may serve as a buffer when particles migrate into an upper portion of the polymer layer, with the result that the semiconductor package may be prevented or minimized from crack or non-adhesion. Accordingly, defects may be avoided and a yield may be improved in fabricating the semiconductor package.

Although various examples have been described and illustrated, it will be understood to those skilled in the art that various changes and modifications may be made without departing from the technical spirit and essential features of the present disclosure. It will be apparent to those skilled in the art that various substitution, modifications, and changes may be thereto without departing from the scope and spirit of the present disclosure.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. For example, the examples of FIGS. 1 to 7 may be combined with each other.

1. A semiconductor package, comprising:
a package substrate;
a plurality of semiconductor dies stacked on the package substrate;
a plurality of wires that connect the plurality of semiconductor dies to the package substrate; and
a mold layer that covers the package substrate, the plurality of semiconductor dies, and the plurality of wires,
wherein each of the plurality of semiconductor dies includes:
a die substrate,
a die dielectric layer on the die substrate,
a bonding pad on the die dielectric layer, and
a first polymer layer that covers the die dielectric layer and exposes the bonding pad,
wherein a plurality of oxygen atoms are between the plurality of semiconductor dies to thereby bond the plurality of semiconductor dies to one another.

2. The semiconductor package of claim 1, wherein the first polymer layer of each of the plurality of semiconductor dies includes silicon.

3. The semiconductor package of claim 2, wherein the first polymer layer is composed of polydimethylsiloxane.

4. The semiconductor package of claim 1, further comprising a plurality of particles in an upper portion of the first polymer layer of each of the plurality of semiconductor dies,
wherein each of the plurality of particles includes at least one of silicon, silicon oxide, or metal.

5. The semiconductor package of claim 1, further comprising an adhesion film between the package substrate and a lowermost one of the plurality of semiconductor dies,
wherein the adhesion film includes a material different from a material of the first polymer layer of each of the plurality of semiconductor dies.

6. The semiconductor package of claim 5, wherein:
the first polymer layer of each of the plurality of semiconductor dies has a first thickness, and
the adhesion film has a second thickness different from the first thickness.

7. The semiconductor package of claim 1, wherein the plurality of semiconductor dies include a first semiconductor die and a second semiconductor die that are sequentially stacked,
wherein the die substrate of the second semiconductor die has a first bottom surface region and a second bottom surface region,
wherein the first bottom surface region is adjacent to the first polymer layer of the first semiconductor die,
wherein the second bottom surface region is covered with the mold layer, and
wherein the oxygen atoms are between the first bottom surface region and the first polymer layer of the first semiconductor die to thereby bond together the first bottom surface region and the first polymer layer of the first semiconductor die.

8. The semiconductor package of claim 1, wherein the package substrate includes:
a body layer;
an upper pad on a top surface of the body layer;
a second polymer layer that covers the top surface of the body layer and exposes the upper pad;
a lower pad on a bottom surface of the body layer; and
a photosensitive dielectric layer that covers the bottom surface of the body layer and exposes the lower pad,
wherein a second plurality of oxygen atoms are between a lowermost one of the plurality of semiconductor dies and the second polymer layer of the package substrate to thereby bond together the lowermost one of the plurality of semiconductor dies and the second polymer layer.

9. The semiconductor package of claim 8, wherein the second polymer layer is composed of polydimethylsiloxane.

10. The semiconductor package of claim 1, wherein the first polymer layer of each of the plurality of semiconductor dies is free of a photosensitive material.

11. A semiconductor package, comprising:
a package substrate;
a plurality of semiconductor dies stacked on the package substrate;
a plurality of wires that connect the plurality of semiconductor dies to the package substrate;
an adhesion film between the package substrate and a lowermost one of the plurality of semiconductor dies; and
a mold layer that covers the package substrate, the plurality of semiconductor dies, and the plurality of wires,
wherein each of the plurality of semiconductor dies includes:
a die substrate,
a die dielectric layer on the die substrate,
a bonding pad on the die dielectric layer, and
a polymer layer that covers the die dielectric layer and exposes the bonding pad, wherein the adhesion film includes a material different from a material of the polymer layer of each of the plurality of semiconductor dies.

12. The semiconductor package of claim 11, comprising a plurality of particles in the polymer layer of each of the plurality of semiconductor dies,
wherein each of the plurality of particles includes at least one of silicon, silicon oxide, or metal.

13. The semiconductor package of claim 11, wherein:
the polymer layer of each of the plurality of semiconductor dies has a first thickness, and the adhesion film has a second thickness different from the first thickness.

14. The semiconductor package of claim 11, wherein the plurality of semiconductor dies include a first semiconductor die and a second semiconductor die that are sequentially stacked,
wherein the die substrate of the second semiconductor die has a first bottom surface region and a second bottom surface region,
wherein the first bottom surface region is adjacent to the polymer layer of the first semiconductor die,
wherein the second bottom surface region is covered with the mold layer, and wherein a plurality of oxygen atoms are between the first bottom surface region and the polymer layer of the first semiconductor die to thereby bond together the first bottom surface region and the polymer layer of the first semiconductor die.

15. The semiconductor package of claim 11, wherein the polymer layer of each of the plurality of semiconductor dies is composed of polydimethylsiloxane.

16. A semiconductor package, comprising:
a package substrate;
a plurality of semiconductor dies stacked on the package substrate and in contact with each other;
a plurality of wires that connect the plurality of semiconductor dies to the package substrate;
an adhesion film between the package substrate and a lowermost one of the plurality of semiconductor dies;
a mold layer that covers the package substrate, the plurality of semiconductor dies, and the plurality of wires; and
a plurality of external connection terminals bonded to a bottom surface of the package substrate,
wherein each of the plurality of semiconductor dies includes:
a die substrate,
a die dielectric layer on the die substrate,
a bonding pad on the die dielectric layer, and
a polymer layer that covers the die dielectric layer and exposes the bonding pad,
wherein the polymer layer of each of the plurality of semiconductor dies has a first thickness, and
wherein the adhesion film has a second thickness different from the first thickness.

17. The semiconductor package of claim 16, wherein the plurality of semiconductor dies include a first semiconductor die and a second semiconductor die that are sequentially stacked,
wherein an oxide bond is provided between a portion of a bottom surface of the die substrate of the second semiconductor die and a top surface of the polymer layer of the first semiconductor die.

18. The semiconductor package of claim 16, wherein the polymer layer of each of the plurality of semiconductor dies is free of a photosensitive material.

19. The semiconductor package of claim 16, further comprising a plurality of particles in the polymer layer of each of the plurality of semiconductor dies,
wherein each of the plurality of particles includes at least one of silicon, silicon oxide, or metal.

20. The semiconductor package of claim 16, wherein the polymer layer of each of the plurality of semiconductor dies is formed of polydimethylsiloxane.

21.-24. (canceled)
